(19) United States
(12) Patent Application Publication
(10) Pub. No.: US 2015/0144950 A1
(43) Pub. Date: May 28, 2015

(54) THIN FILM TRANSISTOR STRUCTURE HAVING BIG CHANNEL-WIDTH AND TFT SUBSTRATE CIRCUIT

(71) Applicant: Shenzhen China Star Optoelectronics Technology Co. Ltd., Shenzhen (CN)

(72) Inventors: Ki Sun Kang, Shenzhen (CN); Chih-sheng Ko, Shenzhen (CN); Wen Chao He, Shenzhen (CN)

(21) Appl. No.: 13/636,702

(22) PCT Filed: Aug. 10, 2012
(86) PCT No.: PCT/CN12/79938

§ 371 Date: Sep. 24, 2012

(30) Foreign Application Priority Data
Aug. 9, 2012 (CN) 201210281691.8

(51) Int. Cl. H01L 27/12; H01L 29/786

(52) U.S. Cl. CPC H01L 27/124; H01L 29/78696
USPC 257/72

(57) ABSTRACT

The present invention discloses a thin film transistor (TFT) structure having big channel-width. The TFT structure comprises a gate, a source and a drain. The source and the drain are respectively be a spiral, and are symmetrical and corresponding to each other to form as a double spiral arrangement. By the source and the drain forming as a symmetrical and corresponding double spiral, the TFT of the present invention can increase the channel-width between the source and the drain, so as to increase width/length rate, so that the charge ability of the TFT can be increased.

### FIELD OF THE INVENTION

The present invention relates to a thin film transistor (TFT) structure having big channel-width and a TFT substrate circuit, and more particularly to a TFT structure of a liquid crystal display (LCD) and a TFT substrate circuit, wherein the TFT structure has a spiral source and drain.

### BACKGROUND OF THE INVENTION

Thin film transistor (TFT) technology is a large-scale semiconductor integrated circuit (IC) manufacture technology which developed from the 1990s of the 20th century, and it is a development base of flat panel display (FPD). Because having characteristics of light portable, low consumption and easy integration, liquid crystal display (LCD) becomes a research spot and leading technology in now information display technology field. It is mainly applied in digital camera, notebook computer, global positioning system (GPS) and varied monitors. With the coming of information society, the application field of the FPD technology is continuously expanding, the research work of this field is also continuously developing to a higher level. Now, the TFT becomes a core component in electronic FPD industry, so according to existing advantages and disadvantages to improve the TFT charge ability becomes an exertion direction for designers.

A conventional TFT mainly includes two types: a symmetry type and an asymmetry type. With the panel size is continuously increases and for getting greater TFT W/L rate (rate of width/length) in a limited space, now the asymmetry type is general used in LCD panels, so as to improve the TFT charge ability in the same space.

Referring to FIG. 1, a partial schematic view of a TFT substrate circuit of an existing LCD is illustrated in FIG. 1. As shown in FIG. 1, a TFT substrate 100 of an existing LCD comprises a plurality of gate lines 110 (horizontal direction) and a plurality of source lines 120 (perpendicular direction), and they form as a matrix circuit. Each of the matrix grids comprises a pixel electrode 130, and each of the pixel electrodes 130 electrically connects with the gate lines 110 and the source lines 120 by a TFT 90.

For detailed description, as shown in FIG. 1, each of the TFTs 90 is a triode structure, which comprises a gate 91, a source 92 and a drain 93. The gate 91 electrically connects with the gate lines 110; the source 92 electrically connects with the source lines 120; and the drain 93 electrically connects with the pixel electrode 130. Hence, by the gate lines 110 and the source lines 120, the TFT substrate circuit can control the pixel electrode 130 (display of the single pixel), so as to combine as a image by the pixel matrix.

Referring to FIG. 2, a schematic top view of the TFT structure of the existing LCD in FIG. 1 is illustrated in FIG. 2, which shows varied shapes of electrodes in a single TFT 90 (in FIG. 1). The TFT 90 is been an asymmetry type TFT, wherein the gate 91 is disposed on the TFT substrate 100 (in FIG. 1), and the gate 91 forms the main area of the entire TFT structure 90. Besides, there is a gate insulating layer disposed on the gate 91 (to simplify the figure, it is not shown and indicated), and the source 92 and the drain 93 are disposed on the gate insulating layer (on the same plane).

Furthermore, the source 92 is a U-shape electrode, and the drain 93 is a I-shape electrode. The I-shape drain 93 is surrounded by the U-shape source 92. Besides, the gate 91 electrically connects with the gate lines; the source 92 electrically connects with the source lines; and the drain 93 electrically connects with the pixel electrode (to simplify the figure, it is not drawn).

As shown in FIG. 2, the area between the source 92 and the drain 93 forms a U-shape channel 94, wherein the length L of the channel 94 is the interval between the source 92 and the drain 93, and the width W of the channel 94 (not indicated) is the length of the U-shape formed between the source 92 and the drain 93 (the dotted-line area in the figure).

Because the TFT charge ability is related to the width W and length L of the channel 94, decreasing the length L and increasing the width W also can improve the TFT charge ability. Hence, when manufacture ability and exposing precision of a exposure machine becomes a bottleneck and is difficult to be broken, and the length L of the channel 94 is fixed and hard to be precisely adjusted, how to increase the width W of the channel 94 becomes vary important in TFT design.

Furthermore, with the gate on array (GOA) technology is more mature, a TFT having big channel-width used in the GOA circuit is widely applied, so it is urgent to need a TFT structure having bigger channel-width.

As a result, it is necessary to provide a TFT structure and a TFT substrate circuit to solve the problems existing in the conventional technologies.

### SUMMARY OF THE INVENTION

A primary object of the present invention is to provide a thin film transistor (TFT) structure having big channel-width and a TFT substrate circuit, so as to solve the problem existing in the conventional technologies that the length and width of a channel is limited in change, so that the charge ability of the TFT cannot be increased.

To achieve the above object, the present invention provides a TFT substrate circuit, comprising:

a plurality of gate lines arranged in a horizontal direction;

a plurality of source lines arranged in a perpendicular direction;

a plurality of pixel electrodes respectively located in a matrix grid which formed by the plurality of gate lines and the plurality of source lines; and

a plurality of TFTs, each of the TFTs respectively corresponds to one of the pixel electrodes, and each of the TFT structures comprising:

a gate electrically connecting with one of the gate lines;

a source electrically connecting with one of the source lines; and

a drain electrically connecting with one of the pixel electrodes;

wherein the source and the drain are disposed on the same plane, and are respectively symmetrical and corresponding to each other forming as a double spiral arrangement; the area between the source and the drain forms a channel; and the rotating circle of the source and the drain are between 1 circle to 2 circles.

To achieve the above object, the present invention further provides a TFT substrate circuit, comprising:

a plurality of gate lines arranged in a horizontal direction;

a plurality of source lines arranged in a perpendicular direction;

a plurality of pixel electrodes respectively located in a matrix grid which formed by the plurality of gate lines and the plurality of source lines; and

a plurality of TFTs, each of the TFTs respectively corresponds to one of the pixel electrodes, and each of the TFT structures comprising:

a gate electrically connecting with one of the gate lines;

a source electrically connecting with one of the source lines; and

a drain electrically connecting with one of the pixel electrodes;

wherein the source and the drain are disposed on the same plane, and are respectively symmetrical and corresponding to each other forming as a double spiral arrangement; the area between the source and the drain forms a channel.

To achieve the above object, the present invention further provides a TFT structure having big channel-width, comprising:

a gate electrically connecting with one of the gate lines;

a source electrically connecting with one of the source lines; and

a drain electrically connecting with one of the pixel electrodes;

wherein the source and the drain are disposed on the same plane, and are respectively symmetrical and corresponding to each other forming as a double spiral arrangement; and the area between the source and the drain forms a channel.

In one embodiment of the present invention, the gate is further provided with a gate insulating layer thereon, and the source and the drain are disposed on the gate insulating layer.

In one embodiment of the present invention, the rotating circle of the source and the drain are between 1 circle to 2 circles.

In one embodiment of the present invention, the area of the TFT is 5850 μm², and the width W of the channel is 324 μm.

In one embodiment of the present invention, the TFT structure is applied in a GOA driver circuit.

Hence, in the present invention, the source and the drain are respectively be a spiral, and are symmetrical and corresponding to each other to form as a double spiral arrangement, so the channel-width between the source and the drain is increased, so as to increase width/length rate, so that the charge ability of the TFT can be increased.

### DESCRIPTION OF THE DRAWINGS

FIG. 1 is a partial schematic view of a thin film transistor (TFT) substrate circuit of a existing liquid crystal display (LCD);

FIG. 2 is a schematic top view of the TFT structure of the existing LCD in FIG. 1;

FIG. 3 is a partial schematic view of a TFT substrate circuit of an LCD according to one embodiment of the present invention;

FIG. 4 is a schematic top view of the TFT structure of the LCD according to one embodiment of the present invention; and

FIG. 5 is a schematic top view of a TFT structure of an LCD according to another embodiment of the present invention.

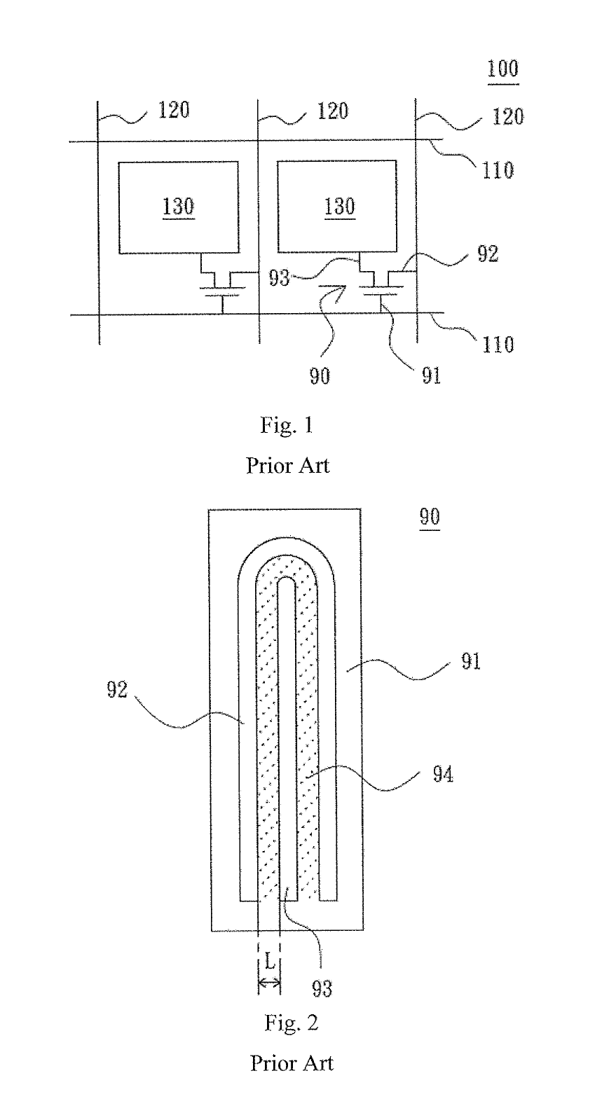

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

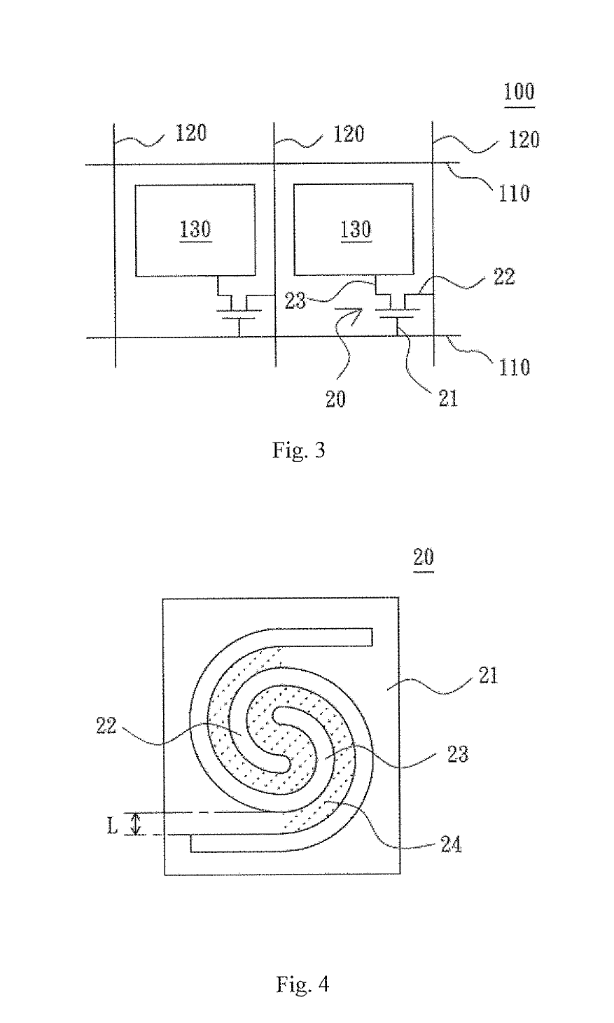

Referring to FIG. 3, a partial schematic view of a TFT substrate circuit of an LCD according to one embodiment of the present invention is illustrated in FIG. 3. As shown in FIG. 3, a TFT substrate 100 of a liquid crystal display (LCD) comprises a plurality of gate lines 110 (horizontal direction) and a plurality of source lines 120 (perpendicular direction),and they form as a matrix circuit. Each of matrix grids comprises a pixel electrode 130, and each of the pixel electrodes 130 electrically connects with the gate lines 110 and the source lines 120 by a TFT 20.

For detailed description, as shown in FIG. 3, each of the TFTs 20 is a triode structure, which comprises a gate 21, a source 22 and a drain 23. The gate 21 electrically connects with the gate lines 110; the source 22 electrically connects with the source lines 120; and the drain 23 electrically connects with the pixel electrode 130. Hence, by the gate lines 110 and the source lines 120, the TFT substrate circuit can control the pixel electrode 130 (display of the single pixel), so as to combine as a image by the pixel matrix.

Referring to FIG. 4, a schematic top view of the TFT structure of the LCD according to one embodiment of the present invention is illustrated in FIG. 4, which shows varied shapes of electrodes in a single TFT 20 (in FIG. 3). The TFT 20 is been an asymmetry type TFT, wherein the gate 21 is disposed on the TFT substrate 100 (in FIG. 3), and the gate 21 forms the main area of the entire TFT structure 20. Besides, there is a gate insulating layer disposed on the gate 21(to simplify the figure, it is not shown and indicated), and the source 22 and the drain 23 are disposed on the gate insulating layer (on the same plane).

Furthermore, the source 22 and drain 23 are respectively been a spiral (they respectively rotate a circle, 360°). The spiral source 22 and drain 23 are symmetrical and corresponding to each other, so they form as a double spiral arrangement. Besides, the gate 21 electrically connects with the gate lines; the source 22 electrically connects with the source lines; and the drain 23 electrically connects with the pixel electrode (to simplify the figure, it is not drawn).

As shown in FIG. 4, the area between the source 22 and the drain 23 forms a channel 24, wherein the channel 24 is a shape of “spiral-in and spiral-out”. The length L of the channel 24 is the interval between the source 22 and the drain 23, and the width W of the channel 24 (not indicated) is the length of the shape of “spiral-in and spiral-out” formed between the source 22 and the drain 23 (the dotted-line area in the figure).

In this embodiment, the area of the TFT 20 is such as 3400 μm², the width W of the channel 24 is such as 161 μm. Because the TFT charge ability is related to the width W and length L of the channel 94, decreasing the length L and increasing the width W also can improve the TFT charge ability. In this embodiment, when the length L of the channel 24 is fixed, by the source 22 and the drain 23 which form as a symmetrical and corresponding double spiral, the width W of the channel 24 is increased, so as to increase W/L rate, so that the charge ability of the TFT 20 can be increased.

Furthermore, with the gate on array (GOA) technology is more mature, a TFT having big channel-width used in the GOA circuit is widely applied, so it is urgent to need a TFT structure having bigger channel-width.

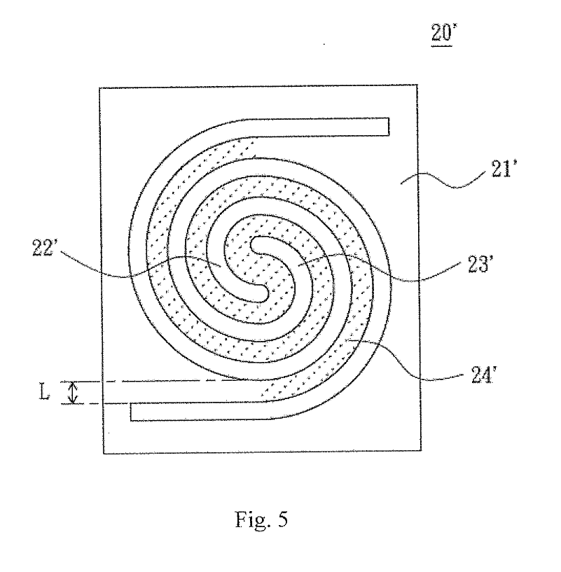

Referring to FIG. 5, a schematic top view of a TFT structure of an LCD according to another embodiment of the present invention is illustrated in FIG. 5. The TFT 20′ of this embodiment is substantially similar to the TFT 20 according to FIG. 4 embodiment of the present invention, so as to use similar terms and numerals, but the difference therebetween is that: in this embodiment, the spiral circle of the source 22′ and the drain 23′ are greater than the spiral circle of the source 22 and the drain 23 in FIG. 4 embodiment, wherein the source 22′ and the drain 23′ are respectively rotate 1.5 circle (540°), so that the width W of the channel 24 (the dotted-line area in the figure) can be increased, so as to increase the W/L rate.

In this embodiment, the area of the TFT 20′ is such as 5850 μm², the width W of the channel 24′ is such as 324 μm.

Additionally, the area of the TFT 20,20′ and the rotating circle of the source 22 and the drain 23 are not limited in the present invention. Preferably, the rotating circle of the source 22 and the drain 23 are between 1 circle (360°) to 2 circles (720°). Hence, the user can design the rotating circle of the source 22 and the drain 23 by actual requirement to get a bigger channel-width, so as to obtain a better charge ability.

As described above, to compare with the traditional technology, the change of the length and width of the TFT is limited, so it is difficult to increase W/L rate to increase the charge ability of the TFT. In the present invention, when the length L of the channel 24,24′ is fixed, by the source 22,22′ and the drain 23,23′ which form as a symmetrical and corresponding double spiral, the width W of the channel 24,24′ is increased, so as to increase W/L rate, so that the charge ability of the TFT 20,20′ can be increased.

The present invention has been described with a preferred embodiment thereof and it is understood that many changes and modifications to the described embodiment can be carried out without departing from the scope and the spirit of the invention that is intended to be limited only by the appended claims.

1. A thin film transistor (TFT) substrate circuit, comprising:
a plurality of gate lines arranged in a horizontal direction;
a plurality of source lines arranged in a perpendicular direction;
a plurality of pixel electrodes respectively located in a matrix grid which formed by the plurality of gate lines and the plurality of source lines; and
a plurality of TFTs, each of the TFTs respectively corresponds to one of the pixel electrodes, and the TFT substrate circuit is characterized in that: each of the TFT structures comprising:
a gate electrically connecting with one of the gate lines;
a source electrically connecting with one of the source lines; and
a drain electrically connecting with one of the pixel electrodes;
wherein the source and the drain are disposed on the same plane, and are respectively symmetrical and corresponding to each other forming as a double spiral arrangement; the area between the source and the drain forms a channel; and the rotating circle of the source and the drain are between 1 circle to 2 circles.

2. The TFT substrate circuit according to claim 1, characterized in that:
the gate is further provided with a gate insulating layer thereon, and the source and the drain are disposed on the gate insulating layer.

3. The TFT substrate circuit according to claim 1, characterized in that:
the area of the TFT is 5850 μm², and the width W of the channel is 324 μm.

4. substrate circuit according to claim 1, characterized in that:
the TFT substrate circuit is a gate on array (GOA) driver circuit.

5. A TFT substrate circuit, comprising:
a plurality of gate lines arranged in a horizontal direction;
a plurality of source lines arranged in a perpendicular direction;
a plurality of pixel electrodes respectively located in a matrix grid which formed by the plurality of gate lines and the plurality of source lines; and
a plurality of TFTs, each of the TFTs respectively corresponds to one of the pixel electrodes, and the TFT substrate circuit is characterized in that: each of the TFT structures comprising:
a gate electrically connecting with one of the gate lines;
a source electrically connecting with one of the source lines; and
a drain electrically connecting with one of the pixel electrodes;
wherein the source and the drain are disposed on the same plane, and are respectively symmetrical and corresponding to each other forming as a double spiral arrangement; and the area between the source and the drain forms a channel.

6. The TFT substrate circuit according to claim 5, characterized in that:
the gate is further provided with a gate insulating layer thereon, and the source and the drain are disposed on the gate insulating layer.

7. The TFT substrate circuit according to claim 5, characterized in that:
the rotating circle of the source and the drain are between 1 circle to 2 circles.

8. The TFT substrate circuit according to claim 5, characterized in that:
the area of the TFT is 5850 μm², and the width W of the channel is 324 μm.

9. substrate circuit according to claim 5, characterized in that:
the TFT substrate circuit is a GOA driver circuit.

10. A TFT structure having big channel-width, characterized in that: the TFT structure comprising:
a gate electrically connecting with one of the gate lines;
a source electrically connecting with one of the source lines; and
a drain electrically connecting with one of the pixel electrodes;
wherein the source and the drain are disposed on the same plane, and are respectively symmetrical and corresponding to each other forming as a double spiral arrangement; and the area between the source and the drain forms a channel.

11. The TFT structure according to claim 10, characterized in that: the gate is further provided with a gate insulating layer thereon, and the source and the drain are disposed on the gate insulating layer.

12. The TFT structure according to claim 10, characterized in that: the rotating circle of the source and the drain are between 1 circle to 2 circles.

13. The TFT structure according to claim 10, characterized in that: the area of the TFT is 5850 μm², and the width W of the channel is 324 μm.

14. The TFT structure according to claim 10, characterized in that: the TFT structure is applied in a GOA driver circuit.
